(19) United States
(12) Patent Application Publication
(10) Pub. No.: US 2020/0313057 A1
(43) Pub. Date: Oct. 1, 2020

(54) HIGH POWER LED ASSEMBLY AND METHOD OF FORMING A HIGH POWER LED ASSEMBLY

(71) Applicant: Lumileds LLC, San Jose, CA (US)

(72) Inventors: Walter Daeschner, San Jose, CA (US); Chong Tat Lim, San Jose, CA (US); Tyan-Shin Go, San Jose, CA (US); Cheng Loong Yong, San Jose, CA (US); Aik-Teng Tan, San Jose, CA (US); Werner Goetz, San Jose, CA (US)

(73) Assignee: Lumileds LLC, San Jose, CA (US)

(21) Appl. No.: 16/833,282

(22) Filed: Mar. 27, 2020

Related U.S. Application Data
(63) Continuation-in-part of application No. 16/370,936, filed on Mar. 30, 2019.
(60) Provisional application No. 62/833,250, filed on Apr. 12, 2019.

(51) Int. Cl. H01L 33/62; H01L 33/56; H01L 33/50; H01L 33/00; H01L 33/60

(52) U.S. Cl. CPC H01L 33/62; H01L 33/56; H01L 33/60; H01L 33/0095; H01L 33/505

(57) ABSTRACT

Systems, apparatus and methods of forming an LED device are described herein. The method includes providing a lead frame and an LED sub-assembly including an LED die attached to a wavelength conversion layer, and an optically transparent sidewall surrounding the LED die, the optically transparent sidewall having a curved or angled profile, attaching the LED sub-assembly to the lead frame, and dispensing an encapsulation material in a space surrounding the LED sub-assembly attached to the lead frame. The LED assembly is a high power LED assembly.

### RELATED APPLICATIONS

The present disclosure is a continuation-in-part of U.S. non-provisional application Ser. No. 16/370,936 entitled “HIGH POWER LED ASSEMBLY AND METHOD OF FORMING A HIGH POWER LED ASSEMBLY” and filed Mar. 30, 2019, and claims priority to U.S. provisional application No. 62/833,250 entitled “HIGH POWER LED ASSEMBLY AND METHOD OF FORMING A HIGH POWER LED ASSEMBLY” and filed Apr. 12, 2019, the disclosures of which are incorporated by reference in their entireties.

### BACKGROUND

There are two general power classifications for light emitting diode (LED) devices: low/medium power LED devices and high power LED devices. These two classes of LEDs can be manufactured in different ways and require different assembly processes to provide the desired characteristics typically associated with each class of LED device.

### SUMMARY

Systems, apparatus and methods of forming a light emitting diode (LED) device are described herein. The method includes providing a lead frame and an LED sub-assembly including an LED die attached to a wavelength conversion layer, and an optically transparent sidewall surrounding the LED die, the optically transparent sidewall having a curved or angled profile, attaching the LED sub-assembly to the lead frame, and dispensing an encapsulation material in a space surrounding the LED sub-assembly attached to the lead frame. The LED assembly is a high power LED assembly.

In other embodiments, a light emitting diode (LED) includes an LED die having a top, a bottom, and sidewalls. Also included is a first layer having a top and a bottom, with the first layer bottom being attached to the top of the LED die, the first layer being sized to be larger than the LED die. An at least partially transparent sidewall layer is attached between the first layer and the sidewalls of the LED die and a reflective layer is attached to the at least partially transparent sidewall layer. Support and electrical connections can be provided by a lead frame with optional base attached to the LED die.

In other embodiments, a method of forming a chip scale light emitting diode (LED) package includes the steps of attaching an LED die having a top, a bottom, and sidewalls to a first layer having a top and a bottom, with the first layer bottom being attached to the top of the LED die. The first layer is sized to be larger than the LED die supports attachment of an at least partially transparent sidewall layer to extend between the first layer and the sidewalls of the LED die.

In other embodiments, a method of forming a chip scale light emitting diode (LED) package includes the steps of providing a chip scale package that includes an LED die having a top, a bottom, and sidewalls, a first layer having a top and a bottom, with the first layer bottom being attached to the top of the LED die, the first layer being sized to be larger than the LED die, and an at least partially transparent sidewall layer that extends between the first layer and the sidewalls of the LED die. The bottom of the LED die in the chip scale package is attached to a lead frame and a reflective layer attached to the at least partially transparent sidewall layer is formed. Optionally, the lead frame can be attached to a base defining a cavity sized to fit the LED die within.

In an embodiment, the at least partially transparent sidewall layer defines a curved or angled surface, and can fully or partially transparent to light of optical wavelengths of interest.

In an embodiment, the reflective layer further comprises a polymeric material mixed with reflective particles.

In an embodiment, the first layer is a wavelength conversion layer.

In an embodiment, the first layer is a transparent layer.

In an embodiment, the top of the first layer is flat.

In an embodiment, a base can be arranged to support the lead frame and define a cavity surrounding the LED die, first layer, and at least partially transparent sidewall layer, with a polymeric material mixed with reflective particles positioned between the base and the at least partially transparent sidewall layer.

In an embodiment, the LED die, first layer, and at least partially transparent sidewall layer comprise a chip scale package.

### BRIEF DESCRIPTION OF THE DRAWINGS

The foregoing Summary as well as the following Detailed Description will be best understood when read in conjunction with the appended drawings. In the drawings:

FIG. 1A is a cross-sectional view of an example LED device;

FIG. 1B is a cross-sectional view of another example LED device;

FIG. 1C is a cross-sectional view of another example LED device;

FIG. 1D is a cross-sectional view of an example LED device;

FIG. 1E is a cross-sectional view of another example LED device;

FIG. 1F is a schematic drawing illustrating a product of a stage of an example method for producing an LED device;

FIG. 1G is a schematic drawing illustrating a product of another stage of the example method for producing an LED device;

FIG. 1H is a schematic drawing illustrating a product of another stage of the example method for producing an LED device;

FIG. 1I is a schematic drawing illustrating a product of another stage of the example method for producing an LED device;

FIG. 1J is a schematic drawing illustrating a product of another stage of the example method for producing an LED device;

FIG. 1K is a flow diagram of an example method of producing an LED device;

FIG. 1L is a flow diagram of an example method of producing an LED device;

FIG. 1M is a flow diagram of an example method of producing an LED device;

FIG. 2A is a diagram showing a Light Emitting Diode (LED) device;

FIG. 2B is a diagram showing multiple LED devices;

FIG. 3 is a top view of an electronics board for an integrated LED lighting system according to some embodiments;

FIG. 4A is a top view of the electronics board with LED array attached to the substrate at the LED device attach region in some embodiments;

FIG. 4B is a diagram of some embodiments of a two channel integrated LED lighting system with electronic components mounted on two surfaces of a circuit board; and

FIG. 5 is a diagram of an example application system.

### DETAILED DESCRIPTION OF THE PREFERRED EMBODIMENTS

Examples of different light illumination systems and/or light emitting diode implementations will be described more fully hereinafter with reference to the accompanying drawings. These examples are not mutually exclusive, and features found in one example may be combined with features found in one or more other examples to achieve additional implementations. Accordingly, it will be understood that the examples shown in the accompanying drawings are provided for illustrative purposes only and they are not intended to limit the disclosure in any way. Like numbers refer to like elements throughout.

It will be understood that, although the terms first, second, third, etc. may be used herein to describe various elements, these elements should not be limited by these terms. These terms may be used to distinguish one element from another. For example, a first element may be termed a second element and a second element may be termed a first element without departing from the scope of the present invention. As used herein, the term “and/or” may include any and all combinations of one or more of the associated listed items.

It will be understood that when an element such as a layer, region, or substrate is referred to as being “on” or extending “onto” another element, it may be directly on or extend directly onto the other element or intervening elements may also be present. In contrast, when an element is referred to as being “directly on” or extending “directly onto” another element, there may be no intervening elements present. It will also be understood that when an element is referred to as being “connected” or “coupled” to another element, it may be directly connected or coupled to the other element and/or connected or coupled to the other element via one or more intervening elements. In contrast, when an element is referred to as being “directly connected” or “directly coupled” to another element, there are no intervening elements present between the element and the other element. It will be understood that these terms are intended to encompass different orientations of the element in addition to any orientation depicted in the figures.

Relative terms such as “below,” “above,” “upper,”, “lower,” “horizontal” or “vertical” may be used herein to describe a relationship of one element, layer, or region to another element, layer, or region as illustrated in the figures. It will be understood that these terms are intended to encompass different orientations of the device in addition to the orientation depicted in the figures.

Semiconductor light emitting devices or optical power emitting devices, such as devices that emit ultraviolet (UV) or infrared (IR) optical power, are among the most efficient light sources currently available. These devices may include light emitting diodes, resonant cavity light emitting diodes, vertical cavity laser diodes, edge emitting lasers, or the like (hereinafter referred to as “LEDs”). Due to their compact size and lower power requirements, for example, LEDs may be attractive candidates for many different applications. For example, they may be used as light sources (e.g., flash lights and camera flashes) for hand-held battery-powered devices, such as cameras and cell phones. They may also be used, for example, for automotive lighting, heads up display (HUD) lighting, horticultural lighting, street lighting, torch for video, general illumination (e.g., home, shop, office and studio lighting, theater/stage lighting and architectural lighting), augmented reality (AR) lighting, virtual reality (VR) lighting, as back lights for displays, and IR spectroscopy. A single LED may provide light that is less bright than an incandescent light source, and, therefore, multi-junction devices or arrays of LEDs (such as monolithic LED arrays, micro LED arrays, etc.) may be used for applications where more brightness is desired or required. Additionally or alternatively, LEDs with increasing active area size may be generated. Multiple LEDs may be combined to replace a legacy light source.

LED devices may be formed by combining an LED sub-assembly with a lead frame. High power LED devices typically require an interposer formed from a ceramic substrate. The lead frame discussed in accordance with the subject matter disclosed herein is an implementation of such an interposer. While ceramic substrates are well suited for high power LED devices, ceramic substrates also have size restrictions, and are costly, which may result in constraints during production that limit the manufacturing processes that can be applied to mass produce high power LED devices with ceramic substrates. As a result, manufacturing LED devices with lead frames with ceramic substrates is expensive and time consuming to manufacture. Accordingly, it may be desirable to provide a high power LED assembly that is cost effective to manufacture that also has efficient light extraction features while maintaining all desirable features of a high efficiency, high power LED.

The present embodiments broadly disclose integrating an LED (e.g., high powered LED) sub-assembly with a lead frame assembly (e.g., high volume lead frame assembly). The embodiments disclosed herein have the high performance characteristics of high power LEDs but are relatively inexpensive and easy to manufacture.

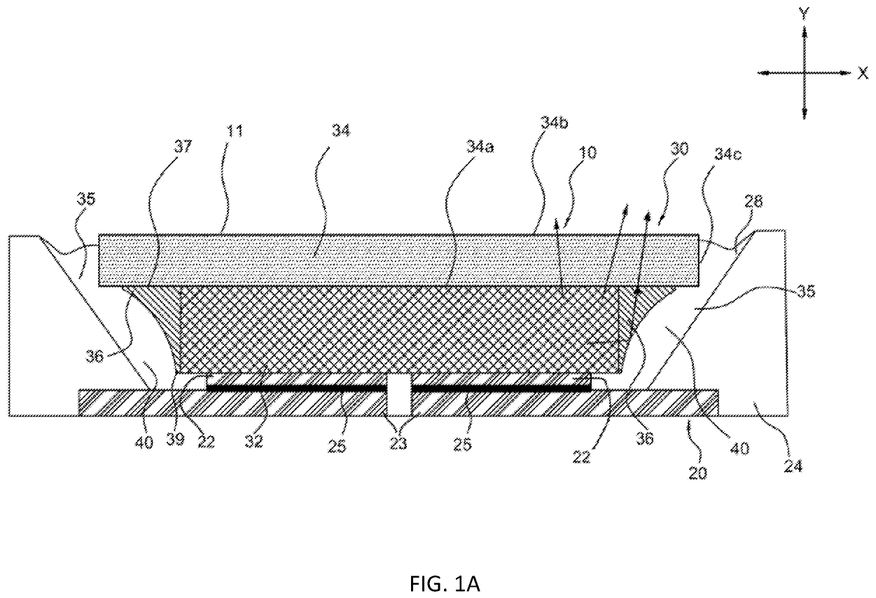

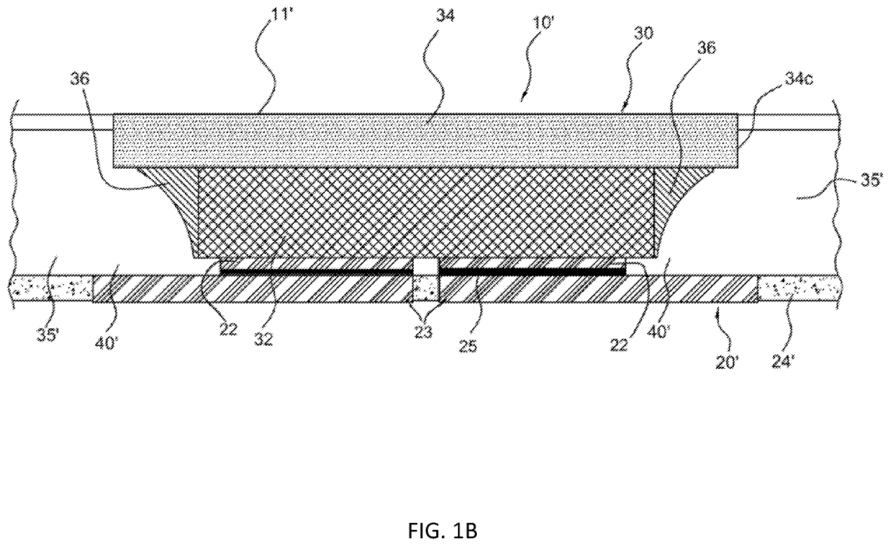

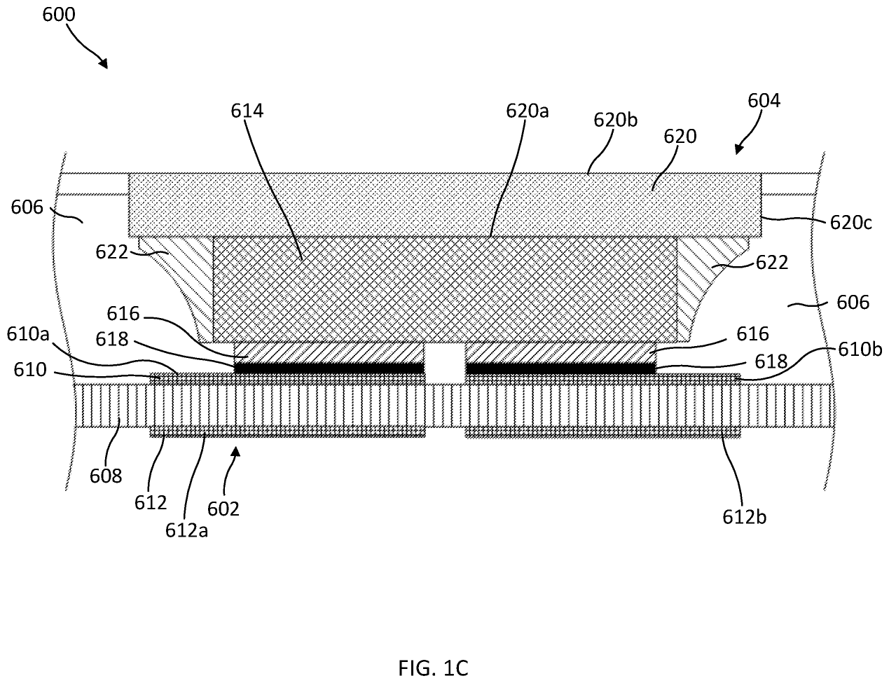

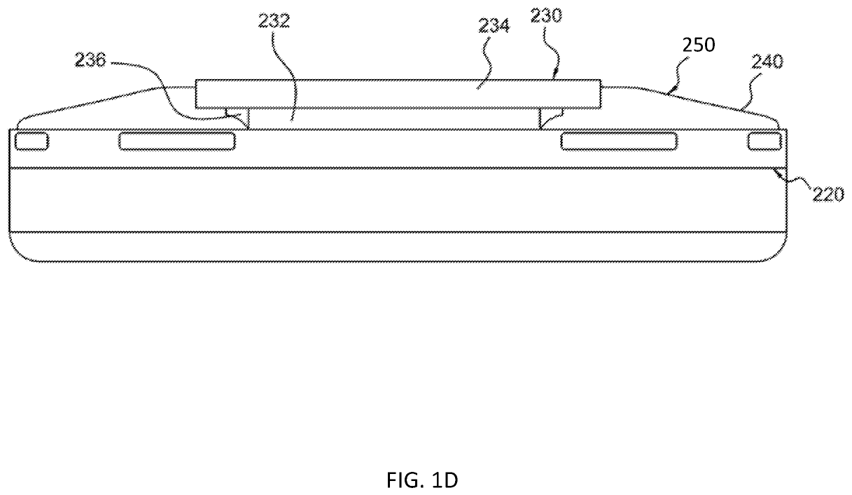

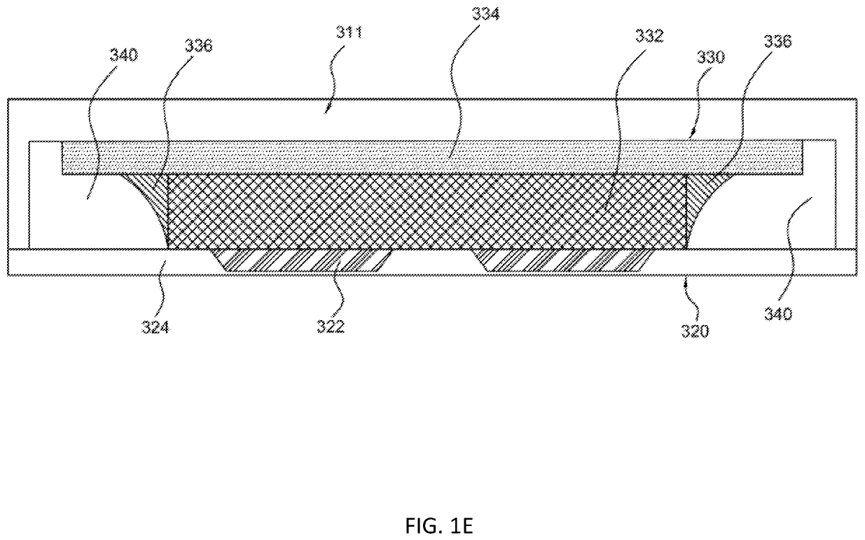

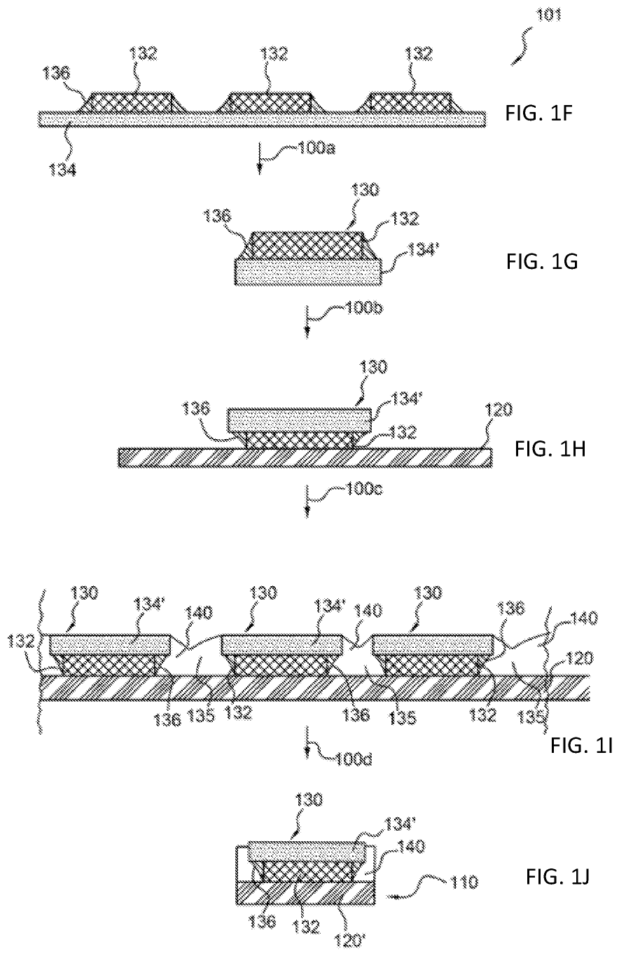

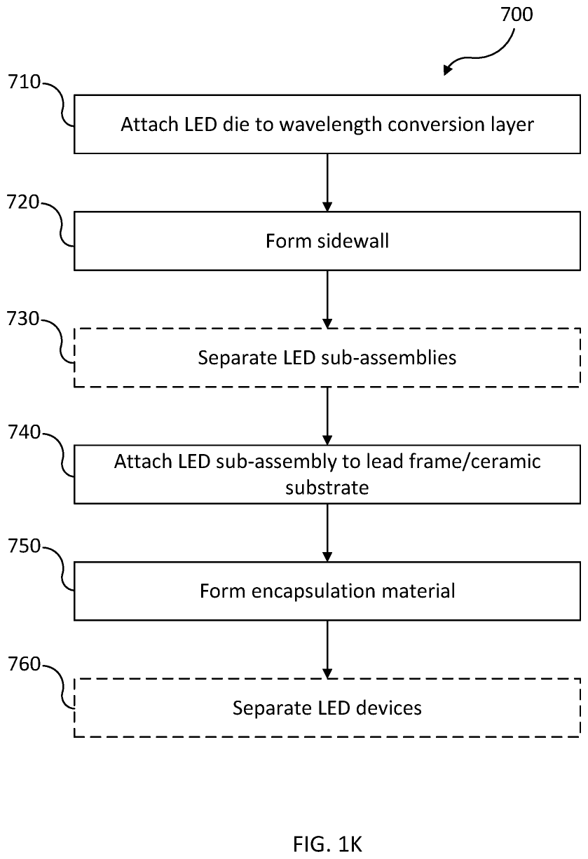

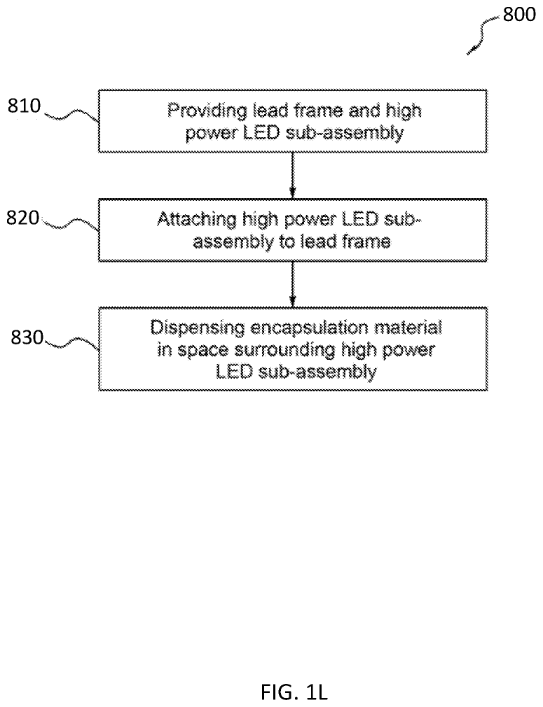

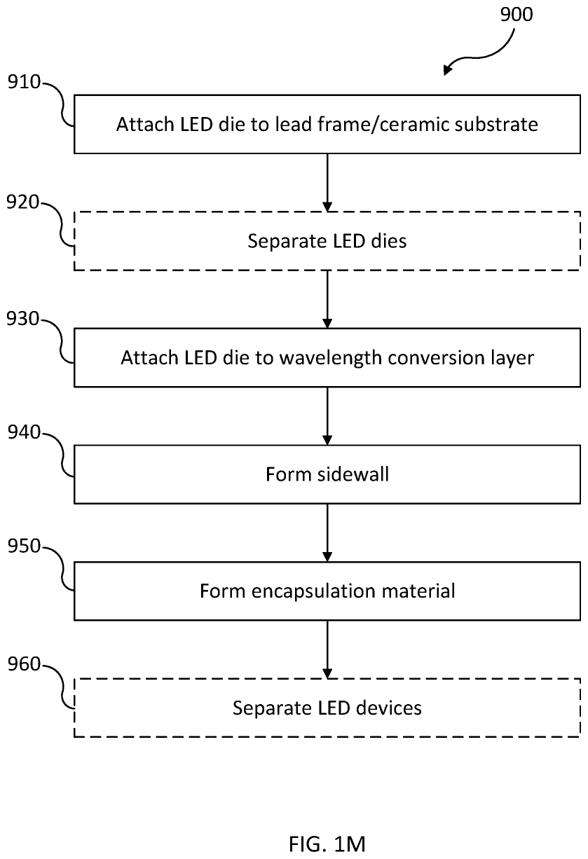

FIG. 1A is a cross-sectional view of an example LED device 10. The illustrated LED device 10 may be a high power LED device. As used herein, the term high power LED device may refer to an LED device having a construction that enables driving the LED device at an input power of greater than, for example, one watt and, for example, provides a concentrated beam from a small optical source size. A high power LED's construction may provide, for example, high luminance from a single package to enable cost effective, single optic and directional fixture designs. A high power LED device, as disclosed herein, may include lead frame or base material formed by, for example, an epoxy molding compound (EMC) process or silicone molding compound. In comparison, a low or mid power LED may be constructed of material such as plastic frames which would not enable the performance, as disclosed herein. In a high power LED device, the light extraction features, which are part of the LED sub-assembly 30 before the LED sub-assembly 30 is attached to the lead frame 20, may enable use of the epoxy or silicone molding compound. As an example, in traditional LED devices, it may be necessary to place a hemispherical dome onto the LED, increasing the difficulty of the manufacturing process; as such a process may be achieved by using a ceramic substrate as a carrier, which may increase the difficulty and/or cost of the process. According to implementations disclosed herein, parts (e.g., metal parts such as copper) which enable effective heat transfer are used. Further, the epoxy or silicone molding compound may act as an electrical insulator while mechanically providing stability for the parts (e.g., metal parts such as copper) which may be needed for thermal and electrical conductivity.

The LED device 10 illustrated in FIG. 1A includes a lead frame 20, an LED sub-assembly 30, and an encapsulation layer or encapsulation material 40.

The lead frame 20 may include metallic contacts 22 embedded in a base 24. In one embodiment, the metallic contacts 22 are formed of copper. The metallic contacts 22 can be formed of any suitable conductive material capable of directing current to the LED sub-assembly 30 and can be formed by an etching or stamping process. The base 24 of the lead frame 20 may be formed of a polymer. In one embodiment, the base 24 is formed by, for example, an epoxy molding compound (EMC) process or silicone molding compound. The LED device 10 may emit light when current is provided by the lead frame 20.

In one embodiment, as best shown in FIG. 1A, the lead frame 20 includes a cavity or pocket 28. The pocket 28 can be formed as part of the molding process or can be stamped or pressed into the base 24. This pocket 28 may be adapted and dimensioned to receive the LED sub-assembly 30.

The lead frame 20 includes interconnects 25 and frame 23, and generally serves as an integrated heat transferor, such as a heat transfer element, and part of the lead frame 20 may be formed of copper. Interconnects 25 may be solder joints or other interconnect material that connect the metallic contacts 22 to the frame 23. The lead frame 20 may connect the LED device 10 to, for example, a PCB board. The thickness of the lead frame or a component of the lead frame may be limited due to etching or stamping based manufacturing technology. Further, there is an inherent trade-off between a gap between an anode and cathode solder pad and a thickness of the lead frame 20 or component of the lead frame 20 in that the gap generally cannot be made smaller than a total thickness of the lead frame 20 or component of the lead frame 20. The embodiments of the LED assembly disclosed herein are based on a 200 pm gap and a 200 pm substrate thickness. However, other gap sizes and substrate thicknesses may be used consistent with the embodiments described herein. The lead frame 20 serves as a heat transferor as heat flows from the LED die 32 through the metallic contacts 22, interconnects 25 and through the frame 23. Notably, heat is transferred in a horizontal direction across the frame 23 and this horizontal dissipation of heat allows the heat to spread and transfer more evenly and effectively into a circuit board and, from there, outwards to a heatsink. Accordingly, lead frame 20 serves as a heat spreader in accordance with the subject matter disclosed herein.

According to an implementation, one or more additional pads in addition to the metallic contacts 22, such as a neutral pad (not shown), may be provided and may provide additional heat dissipation. Further, inside the lead frame 20 there may be a Zener diode (not shown) which may protect the LED die 32 against transient voltage. Such a diode may be a Transient Voltage Suppressor (TVS).

While the lead frame 20 illustrated in FIG. 1A has a cavity formed therein to accommodate the LED sub-assembly, other shapes of lead frames are possible. For example, FIG. 1B is a cross-sectional view of another example LED device that has a lead frame 20′ formed as a continuously flat plate having a uniform cross-sectional profile. The term “continuously flat,” as used herein, may indicate that the lead frame 20′ has a generally flat and constant cross-sectional profile with the exception of varying cross-sections for the metallic contacts.

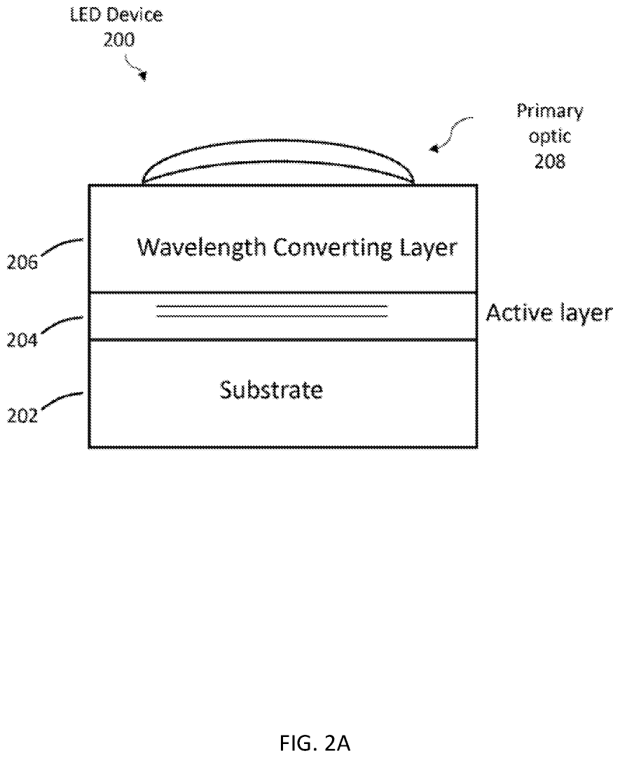

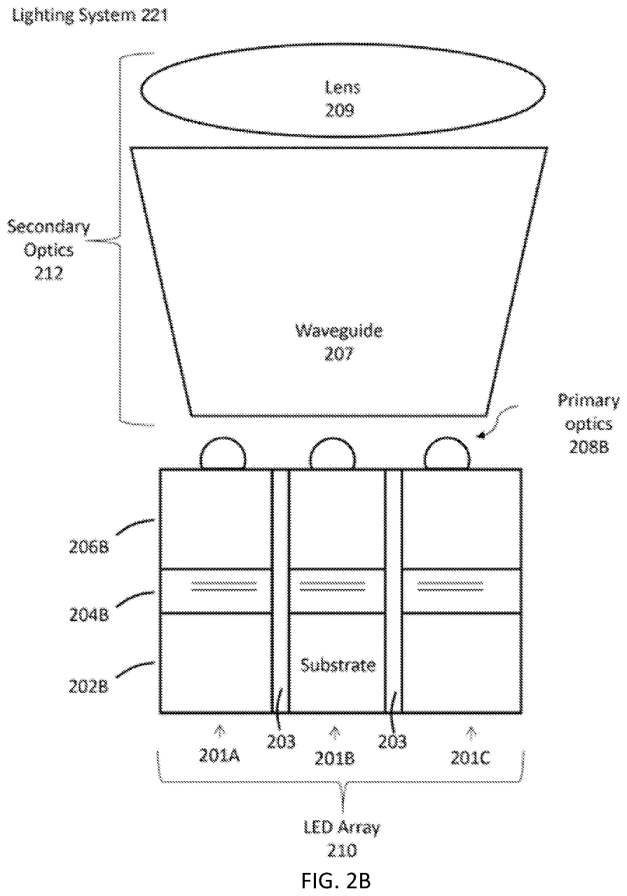

Referring back to FIG. 1A, the LED sub-assembly 30 includes an LED die 32, a wavelength conversion layer 34, and a sidewall 36. The LED die 32 may include the substrate 202 and active layer 204 illustrated in FIG. 2A and described in more detail below. In some embodiments, the LED die 32 may be formed of sapphire. The wavelength conversion layer 34 may be the same as, or similar to, the wavelength conversion layer 206 illustrated in FIG. 2A and described in detail below. The sidewall 36 may surround the LED die 32 and may be formed from a transparent material to allow emitted light to not be emitted out of the LED device via the wavelength conversion layer 206 but also to be emitted through a side wall of the LED and then transmitted through the sidewall 36, as shown by the arrows in FIG. 1A. In some embodiments, the sidewall 36 may be formed of a silicone-based material without fillers or transparent filters. The curvature of sidewall 36 may be optimized such that all or almost all (e.g., substantially all) photons exiting the LED die 32 are reflected towards the wavelength conversion layer 206. The sidewall 36 may have an angled or curved profile, which may promote flow of an encapsulation material 40 into the area surrounding the LED sub-assembly 30 between the LED sub-assembly 30 and the lead frame 20. As shown in FIG. 1A, the curve may be concave relative to the LED die 32. The sidewall 36 may be at least partially transparent, and optically transparent for a wavelength of interest. According to an implementation, the sidewall 36 may be partially transparent for a wavelength of interest. A wavelength of interest may be the wavelength emitted by the LED die 32 and/or the light emitted after converting via the wavelength conversion layer 34. As shown in the FIGS. 1A through 1E, the wavelength conversion layer 34 can be sized to be larger than the LED die to allow attachment of the transparent at a wavelength of interest curved or angled sidewall 36.

According to an implementation, wavelength conversion layer 34 may not be present or may be replaced by a transparent layer (e.g., a layer that may not contain wavelength converting particles) such that light emitted by the LED die 32 is not converted and is emitted as is. In such an implementation, for example, the LED die 32 may emit blue light which is then emitted from the LED device 10 without being converted. This transparent layer can be sized to be larger than the LED die to allow attachment of the transparent layer at a wavelength of interest curved or angled sidewall 36. In certain embodiments, optics or additional wavelength conversion layers can attached to the transparent layer.

The sidewall 36 has a height (measured along axis Y in FIG. 1A) that may be equal to or greater than a height of the LED die 32. The sidewall 36 may also have a relatively wider base 37 that abuts the wavelength conversion layer 34 and a narrower end or tip 39 extending towards the lead frame 20. The wavelength conversion layer 34 (or transparent layer) may be wider than the LED die 32 on all sides to allow attachment of curved or angled sidewall 36 (width being measured along the X-axis illustrated in FIG. 1A), and the LED die 32 may be thicker than the wavelength conversion layer 34 (thickness being measured along the Y-axis illustrated in FIG. 1A). One of ordinary skill in the art would understand that the relative sizes and dimensions of the LED sub-assembly 30 components can be varied depending on the specific requirements of a particular application.

The wavelength conversion layer 34 may have a generally flat profile defined by a first surface 34a adjacent the LED die 32 and a second surface 34b opposite from the first surface 34a. For example, the wavelength conversion layer 34 may be a platelet (e.g., ceramic phosphor plate) or film. In contrast, a wavelength conversion layer in low power or mid power LEDs is typically deposited on the LED die in the form of a sludge or paste, which may be a phosphor mixed with silicone. Thus, as compared to wavelength conversion layers in low power or mid power LEDs, the wavelength conversion layer 34 described herein may have a discrete and well-defined shape.

The LED sub-assembly 30 may be prepared as a package prior to installation with the lead frame 20. As used herein, the term package may refer to components that are attached or fixed to each other such that the package can be handled or picked up with each of the components attached or fixed to each other. According to an implementation, the LED sub-assembly 30 may be fully assembled prior to attachment to the lead frame 20.

The LED sub-assembly 30 may be a chip scale package type LED sub-assembly. Direct contact between contacts of the LED sub-assembly 30 and the metallic contacts 22 of the lead frame 20 may provide highly efficient thermal resistance and does not require connection wires.

The encapsulation material 40 may be formed from a reflective material, such as a polymeric material mixed with reflective particles. The encapsulation material may surround the LED sub-assembly 30 to both reflect light emitted by the LED die 32 and stabilize the LED sub-assembly. The encapsulation material 40 preferably includes a polymeric material mixed with reflective particles. In one embodiment, the encapsulation material 40 may include silicone mixed with titanium oxide (TiOx) particles. In some embodiments, the encapsulation material 40 may be formed of a silicone base infused with TiOx and, in some embodiments, additional fillers (such as fibers that can make the encapsulation material 40 more stable).

The encapsulation material 40 may be deposited into the space 35 surrounding the LED sub-assembly 30 between the LED sub-assembly 30 and the lead frame 20. The encapsulation material 40 can be sprayed, poured, or otherwise deposited into this space 35. The encapsulation material 40 may be deposited in the space 35 in an uncured state such that the encapsulation material 40 flows into the space 35 based on capillary action. In the uncured state, the encapsulation material 40 is fluid. Once the encapsulation material 40 fully surrounds the LED sub-assembly 30 and is settled, the encapsulation material 40 may be cured such that it hardens in place. The encapsulation material 40 can be cured via any known curing technique such as, for example, thermal or optical curing.

The rigidity of the encapsulation material 40 may reinforce the LED device 10 and protect the components within the LED sub-assembly 30. As shown in FIGS. 1A and 1B, the encapsulation material 40 and the encapsulation material 40′, respectively, covers a lateral surface 34c of the wavelength conversion layer 34. The space 35 can either have a conical profile as shown in FIG. 1A, or the space 35′ can have an open profile as shown in FIG. 1B.

Regarding the LED device 10′ illustrated in FIG. 1B, the space 35′ may extend to an adjacent LED assembly, although not illustrated in FIG. 1B. FIG. 11, which is described in more detail below with respect to the method of producing, shows the space 135 having an open profile such that the space 135 extends between neighboring LED sub-assemblies. Based on the embodiments disclosed herein, the overall arrangement of LED sub-assemblies 30 on the lead frame 20 can be varied. In embodiments, such as in FIG. 1A where the lead frame 20 includes pockets 28, spacing between adjacent LED sub-assemblies may be determined based on the orientation of the pockets 28, where each of the LED sub-assemblies may include one or more of the features of the LED sub-assembly 30. In embodiments, such as illustrated in FIG. 1B, where the lead frame 20 includes a flat base (i.e., lacking cavities or pockets), the LED sub-assemblies may be positioned in a variety of orientations on the lead frame 20. Once the LED sub-assemblies 30 are positioned on the lead frame 20, the encapsulation material 40 may be deposited to fill voids between the LED sub-assemblies 30.

The LED device 10 and the LED device 10′ shown in FIGS. 1A and 1B have generally flat upper surface 11 and generally flat upper surface 11′. The term generally flat as used herein with respect to the upper surface 11 and the upper surface 11′ may indicate that the upper surface 11 and the upper surface 11′ lacks any protrusions, bulges, domes, etc. The LED assembly described herein has comparable or improved extraction efficiency as compared to conventional LED assemblies that include a hemispherical dome (without need for the dome).

As described herein, the LED sub-assembly 30 can be produced in a relatively large volume due to the lack of a ceramic substrate, which previously limited production to making the substrate in 4 inch x 4 inch pieces. Further, the lead frame described herein can be produced in large volume based on the materials required to form the base.

FIG. 10 is a cross-sectional view of another example LED device 600. The LED device 600 may include one or more of the features of the LED device 10 and/or the LED device 10′. For example, elements of the LED device 600 with corresponding elements within the LED device 10 and/or the LED device 10′ may include one or more of the features of the corresponding elements. The LED device 600 may be a high power LED device.

The LED device 600 may include a ceramic substrate 602, an LED sub-assembly 604, and an encapsulation layer or encapsulation material 606. The ceramic substrate 602 may include a ceramic core 608 with a first metal element 610 on a first side of the ceramic core 608 and a second metal element 612 on a second side of the ceramic core 608, the second side of the ceramic core 608 being opposite from the first side of the ceramic core 608. The first metal element 610 may comprise a first metal element piece 610a and a second metal element piece 610b. The first metal element piece 610a may form an anode of the first metal element 610 for coupling to the LED die 614 and the first metal element piece 610b may form a cathode of the first metal element 610 for coupling to the LED die 614. The second metal element 612 may comprise a second metal element piece 612a and a second metal element piece 612b. The second metal element piece 612a may form an anode of the second metal element 610 and the second metal element piece 612b may form a cathode of the second metal element 610. One or more vias, and/or other conductive structures, may extend through the ceramic core 608, and couple the first metal element 610 and the second metal element 612 to allow electrical conduction between the first metal element 610 and the second metal element 612. For example, a portion of the vias may extend between the first metal element piece 610a and the second metal element piece 612a to couple the first metal element piece 610a and the second metal element piece 612a. Another portion of the vias may extend between the first metal element piece 610b and the second metal element piece 612b to couple the first metal element piece 610a and the second metal element piece 612b. In some embodiments, the first metal element 610 and the second metal element 612 may be formed of copper. In other embodiments, the first metal element 610 and the second metal element 612 may be formed of any suitable conductive material capable of conducting current. The ceramic core 608 may be formed of ceramic. The ceramic core 608 may be thicker than the first metal element 610 and the second metal element 612. For example, the ceramic core 608 may have a thickness of approximately 350 microns and each of the first metal element 610 and the second metal element 612 may have a thickness of approximately 60 microns in some embodiments. The ceramic core 608 may be wider than the first metal element 610 and the second metal element 612, where a portion of the ceramic core 608 may extend outside from between the first metal element 610 and the second metal element 612.

The LED sub-assembly 604 may be coupled to the ceramic substrate 602. In particular, an LED die 614 of the LED sub-assembly 604 may be coupled to the ceramic core 608. The LED die 614 may include a substrate (such as the substrate 202 illustrated in FIG. 2A) and an active layer (such as the active layer 204 illustrated in FIG. 2A) and described in more detail below. In some embodiments, the LED die 614 may be formed of sapphire. The LED die 614 may emit light when power is applied to the LED die 614, where the LED die 614 may emit the light from multiple sides of the LED die 614.

One or more metallic contacts 616 and one or more interconnects 618 may be located between the ceramic substrate 602 and the LED die 614, where the metallic contacts 616 and the interconnects 618 may couple the LED die 614 with the ceramic substrate 602. The metallic contacts 616 may abut the LED die 614. In some embodiments, the metallic contacts 616 may be formed of copper. The metallic contacts 616 can be formed of any suitable conductive material capable of conducting current.

The interconnects 618 may be located between the metallic contacts 616 and the ceramic substrate 602, where the interconnects 618 may abut the ceramic core 608. The interconnects 618 may comprise solder joints or other interconnect material that couples the metallic contacts 616 to the ceramic substrate 608. The metallic contacts 616 and the interconnects 618 may electrically couple the LED die 614 and the ceramic substrate 602, thereby facilitating conduction of current between the ceramic substrate 602 and the LED die 614.

The ceramic substrate 602 may couple the LED die 614 to an element for providing power and/or control signals to the LED die 614. For example, the ceramic substrate 602 may couple the LED die 614 to a PCB board, where the PCB may provide power and/or control signals to the LED die 614. The power and/or control signals to the LED die 614 can cause the LED die 614 to emit light.

The LED sub-assembly 604 may further include a wavelength conversion layer 620. The wavelength conversion layer 620 may be located on an opposite side of the LED die 614 from the ceramic substrate 602, where the wavelength conversion layer 620 may abut the LED die 614. The wavelength conversion layer 620 may be the same as, or similar to the wavelength conversion layer 206 illustrated in FIG. 2A and described in detail below. The wavelength conversion layer 620 may have a width greater than a width of the LED die 614 such that a portion of the wavelength conversion layer 620 extends outside of the footprint of the LED die 614. The LED die 614 may have a thickness greater than a thickness of the wavelength conversion layer 620 in some embodiments. The wavelength conversion layer 620 may have a generally flat profile defined by a first surface 620a adjacent the LED die 614 and a second surface 620b opposite from the first surface 620a. For example, the wavelength conversion layer 620 may be a platelet (e.g., ceramic phosphor plate) or film. The wavelength conversion layer 620 may have a discrete and well-defined shape as compared to wavelength conversion layers in low power or mid power LEDs. The wavelength conversion layer 620 may convert a wavelength of light emitted from the LED die 614 and/or filter the light emitted from the LED die 614 to a wavelength of light to be omitted from the LED device 600

In some embodiments, the wavelength conversion layer 620 may not be present or may be replaced by a transparent layer (e.g., a layer that may not contain wavelength converting particles) such that light emitted by the LED die 614 is not converted and is emitted as is. In such embodiments, for example, the LED die 614 may emit blue light which is then emitted from the LED device 600 without being converted. This transparent layer can be sized to be larger than the LED die 614 such that a portion of the transparent layer extends outside of the footprint of the LED die 614. In certain embodiments, optics or additional wavelength conversion layers can attached to the transparent layer.

The LED sub-assembly 604 may further include a sidewall 622. The sidewall 622 may extend around the sides of the LED die 614 and may surround the LED die 614. The sidewall 622 may abut at least a portion of the portion of the wavelength conversion layer 620 that extends outside of footprint of the LED die 614 and extend along the sides of the LED die 614 toward an opposite surface of the LED die 614 from the wavelength conversion layer 620. The sidewall 622 may be formed of a transparent material to allow light emitted from the LED die 614 to pass through the sidewall 622. The light that may pass through the sidewall 622 may be emitted through side walls of the LED die 614, as shown by the arrows in FIG. 1A. In some embodiments, the sidewall 622 may be formed of a silicone-based material without fillers or transparent filters. The sidewall 622 may have an angled or curved profile at a side of the sidewall 622 opposite from the LED die 614. In some embodiments, the curve of the sidewall 622 may be concave relative to the LED die 614. The sidewall 622 may be at least partially transparent, and optically transparent for a wavelength of interest. In some embodiments, the sidewall 622 may be partially transparent for a wavelength of interest. A wavelength of interest may be the wavelength emitted by the LED die 614 and/or a wavelength of a light to be emitted from the LED device 600.

The LED device 600 may further include the encapsulation layer and/or encapsulation material 606. The encapsulation material 606 may be located on sides of the LED sub-assembly 604 and may surround the LED sub-assembly 604 on the sides of the LED sub-assembly 604. The encapsulation material 606 may be located between the ceramic substrate 602 and the second surface 620b of the wavelength conversion layer 620. In particular, the encapsulation material 606 may abut the ceramic substrate 602 and the encapsulation material 606 may extend toward the second surface 620b of the wavelength conversion layer 620 such that a surface of the encapsulation material 606 opposite from the ceramic substrate 602 is level with the second surface 620b or located between the second surface 620b and the ceramic substrate 602. The encapsulation material 606 may abut the LED sub-assembly 604 and fill the space around the LED sub-assembly 604. In particular, the encapsulation material 606 may abut the sidewall 622 and may abut at least a portion of each of the sides of the wavelength conversion layer 620. A portion of the encapsulation material 606 may abut the angled or curved portion of the sidewall 622 and the portion of the encapsulation material 606 may form an angled or curved profile abutting the angled or curved portion of the sidewall 622.

The encapsulation material 606 may be formed of a reflective material, such as a polymeric material mixed with reflective particles. In some embodiments, the encapsulation material 606 may comprise silicone mixed with TiOx particles. In some embodiments, the encapsulation material 606 may be formed of a silicone base infused with TiOx and, in some embodiments, additional fillers (such as fibers that can make the encapsulation material 606 more stable). The encapsulation material 606 may reflect light that contacts the encapsulation material 606, such as light emitted from the LED die 614. For example, light that passes through the sidewall 622 may contact the encapsulation material 606 and be reflected by the encapsulation material 606. Due to the curve of the portion of the encapsulation material 606, the light from the LED die 614 that contacts the encapsulation material 606 may be reflected toward the wavelength conversion layer 620 to be emitted from the LED device 600.

The encapsulation material 606 may further provide rigidity to the LED device 600. For example, the rigidity of the encapsulation material 606 may reinforce the LED device 600 and protect the components within the LED sub-assembly 604. The encapsulation material 606 may cover a lateral surface 620c of the wavelength conversion layer 620. The encapsulation material 606 may can either have a conical profile (such as the conical shape of the encapsulation material 40 shown in FIG. 1A), or an open profile as shown in the illustrated embodiment.

FIG. 1D is a cross-sectional view of an assembled LED device 250. The lead frame 220, the LED sub-assembly 230, the die 232, the wavelength conversion layer 234, the sidewall 236, and the encapsulation material 240 may each correspond to the lead frame 20, LED sub-assembly 30, LED die 32, wavelength conversion layer 34, sidewall 36, and encapsulation material 40 shown in FIGS. 1A and 1B.

FIG. 1E is a photograph of another example of a cross-section of an assembled LED device 311. The lead frame 321, contacts 322, base 324, LED sub-assembly 330, die 332, wavelength conversion layer 334, sidewall 336, and encapsulation material 340 may each correspond to the lead frame 20, metallic contacts 22, base 24, LED sub-assembly 30, LED die 32, wavelength conversion layer 34, sidewall 36, and encapsulation material 40 shown in FIGS. 1A and 1B.

FIGS. 1F-1J illustrate schematic drawings illustrating products of stages of an example method for producing an LED device, such as the LED device 10 of FIG. 1A, the LED device 10′ of FIG. 1B, and the LED device 600 of FIG. 10. For example, an LED device 110 shown in FIG. 1J may comprise the LED device 10, the LED device 10′, or the LED device 600 in different embodiments. FIGS. 1F-1J illustrate five steps for manufacturing the LED device 110. One of ordinary skill in the art would understand that more or less steps can be involved. Additionally, any of the steps may be combined to be performed at the same time. The order of these steps can also be altered such that any one or more of the steps are performed in a different sequence than illustrated in FIGS. 1F-1J.

FIG. 1F illustrates a semi-finished LED sub-assembly including a wavelength conversion layer 134 sheet and a plurality of dies 132 deposited onto the wavelength conversion layer 134. Sidewalls 136 are deposited around the dies 132.

As shown in FIG. 1F, the wavelength conversion layer 134 may be diced to provide individual LED sub-assemblies 130 that include the die 132, the sidewall 136, and a portion of the wavelength conversion layer 134′ (100a). The LED sub-assemblies 130 or LED packages can be individually handled.

As shown in FIG. 1G, the lead frame 120 may be attached to the LED package or sub-assembly 130 (100b). This attachment can be achieved via soldering or any other method. In embodiments, the lead frame 120 directly contacts the die 132, which may improve thermal resistance for the assembly.

As shown in FIG. 1H, multiple LED sub-assemblies 130 may be attached to the lead frame 120 (100c). Based on the placement of the LED sub-assemblies 130 on the lead frame 120, a space 135 may defined between adjacent LED sub-assemblies 130. This space 135 may be subsequently filled by depositing an encapsulation material 140. Once settled, the encapsulation material 140 may be cured and hardened.

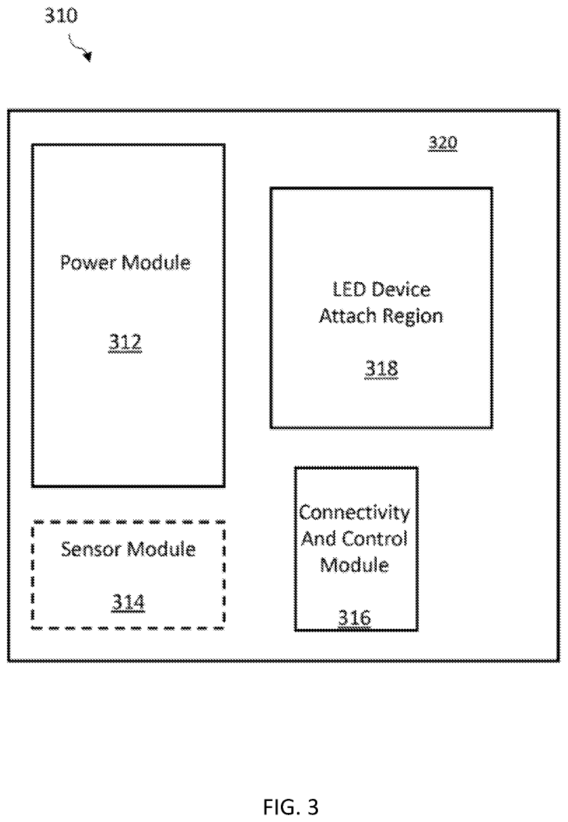

As shown in FIG. 11, the structure formed by the multiple LED sub-assemblies 130 attached to the lead frame 120 may be diced to provide individual LED sub-assemblies 130 (100d) such that an LED device 110 is fully formed. As shown in FIG. 1J, for example, the fully formed LED device 110 may include a single LED sub-assembly 130 (that may include the die 132, wavelength conversion layer 134′, and sidewall 136), the lead frame 120′, and the encapsulation material 140. This LED device 110 may be handled for further processing or assembled into a larger LED array. Example LED systems are shown in FIGS. 3, 4A, 4B, 4C, 4D, 4E and 5, and described in detail below, that may include an LED array, or space for attachment of an LED array, that may include multiple LED devices as described above.

FIG. 1K is a flow diagram of an example method 700 for producing an LED device according to some embodiments. For example, the method 700 may be utilized for producing the LED device 10 of FIG. 1A, the LED device 10′ of FIG. 1B, and/or the LED device 600 of FIG. 10.

In stage 710 of the method 700, an LED die (such as the LED die 32, and/or the LED die 614) may be attached to a wavelength conversion layer (such as the wavelength conversion layer 34, and/or the wavelength conversion layer 620). In stage 720 of the method 700, sidewalls (such as sidewall 36, and/or sidewall 622 may be formed. Depending on the embodiment of the method 700, the stage 710 and the stage 720 can be performed together or performed separately.

In some embodiments of the method 700 where stage 710 and stage 720 are performed together, silicone may be applied to a surface of either or both of the LED die and the wavelength conversion layer. The silicone may be applied to the center of the surface or surfaces. A certain amount of silicone (such as between 1 milligram and 999 milligrams) may be applied to the surface or surfaces. The silicone may be applied to a surface of either or both of the LED die and the wavelength conversion layer that is to be attached against the other component. The silicone may be the same material as the material of the sidewall 36 and/or the sidewall 622 and may be applied in an uncured state. The LED die and the wavelength conversion layer may be positioned against each other with the surface or surfaces of the LED die and/or the wavelength conversion layer abutting the other component. As the LED die and the wavelength conversion layer are positioned against each other, a portion of the silicon may be forced outside the area between the LED die and the wavelength conversion layer, and may extend around the sides of the LED die. Due to capillary forces, the portion of the silicon forced outside of the area between the LED and the wavelength conversion layer may form the shape of the sidewall 36 and/or the sidewall 622. For example, the portion of the silicone may form the angled or curved profile shown by the sidewall 36 and/or the sidewall 622. The angle or curvature of the profile formed by the silicone may depend on the amount of silicone applied to the surface or surfaces. With the LED die and the wavelength conversion layer positioned against each other, the silicone may be cured, thereby attaching the LED die to the wavelength conversion layer and forming the sidewall.

In some other embodiments of the method 700 where stage 710 and stage 720 are performed separately, the wavelength conversion layer may be partially cured and the LED die may be positioned against the wavelength conversion layer while partially cured in stage 710. The material of the partially cured wavelength conversion layer may form a bond with the LED die when the LED die is positioned against the wavelength conversion layer. The wavelength conversion layer may then be fully cured and the LED die may be attached with the wavelength conversion layer to complete stage 710. In 720 silicone may be applied to the sides of the LED die after the LED die has been attached with the wavelength conversion layer. The silicone may be applied in an uncured state. Due to capillary forces, the silicone may form the shape of the sidewall 36 and/or the sidewall 622. For example, the silicone may form the angled or curved profile shown by the sidewall 36 and/or the sidewall 622. The angle or curvature of the profile formed by the silicone may depend on the amount of silicone applied to the sides of the LED die. The silicone may be cured, thereby forming the sidewall.

FIG. 1F illustrates a product that may be produced by performing stage 710 and stage 720. In particular, one or more LED dies 132 may be attached to a wavelength conversion layer 134. The LED dies 132 may include one or more of the features of the LED die 32 and/or the LED die 614, and the wavelength conversion layer 134 may include one or more of the features of the wavelength conversion layer 34 and/or the wavelength conversion layer 620. In the illustrated embodiment, three LED dies 132 are illustrated attached to the wavelength conversion layer 134. Further, sidewalls 136 may be formed around each of the LED dies 132. The sidewalls 136 may include one or more of the features of the sidewall 36 and/or the sidewall 622. In the illustrated embodiment, the sidewall 136 is labeled for one of the LED dies 132 for brevity. The product may be semi-finished sub-assemblies, where the semi-finished LED sub-assemblies are connected by the wavelength conversion layer 134.

In stage 730, LED sub-assemblies are separated. In particular, the wavelength conversion layer may be diced to separate LED sub-assemblies formed with the wavelength conversion layer from each other. The wavelength conversion layer may be cut between sidewalls of adjacent LED dies to dice the separate LED sub-assemblies. The dicing may result in each of the LED sub-assemblies being divided into separate LED sub-assemblies. In some embodiments, stage 730 may be omitted, such as where a single LED die is attached to a wavelength conversion layer.

FIG. 1G illustrates a product that may be produced by performing stage 730. In particular, an individual LED sub-assembly 130 is illustrated. The LED sub-assembly 130 may include one or more of the features of the LED sub-assembly 30 and/or the LED sub-assembly 604

In stage 740, an LED sub-assembly may be attached to a lead frame (such as the lead frame 20 and/or the lead frame 20′) or a ceramic substrate (such as the ceramic substrate 602). Attaching the LED sub-assembly to the lead frame or the ceramic substrate may include positioning the LED sub-assembly on the lead frame or the ceramic substrate. Positioning the LED sub-assembly on lead frame or the ceramic substrate may include aligning metallic contacts (such as the metallic contacts 22 and/or the metallic contacts 616) and interconnects (such as the interconnects 25 and/or the interconnects 618) with the LED die and the lead frame or the ceramic substrate. In some embodiments, the metallic contacts and the interconnects may be connected to the LED sub-assembly, and the metallic contacts and the interconnects may be utilized for soldering the LED sub-assembly to the lead frame or the ceramic substrate to attach the LED sub-assembly to the lead frame or the ceramic substrate. Soldering the LED sub-assembly to the lead frame or the ceramic substrate may further electrically couple the LED sub-assembly to the lead frame or the ceramic substrate.

FIG. 1H illustrates a product that may be produced by performing stage 740. In particular, an LED die 132 is illustrated attached to a lead frame 120. The lead frame 120 may include one or more of the features of the lead frame 20 and/or the lead frame 20′. In some embodiments, the lead frame 120 may be replaced by a ceramic substrate. The ceramic substrate may include one or more of the features of the ceramic substrate 602.

In stage 750, an encapsulation material may be formed. The encapsulation material may be formed on a lead frame or a ceramic substrate, and around an LED sub-assembly on the lead frame or the ceramic substrate. In embodiments where there are multiple LED sub-assemblies attached to the lead frame or the ceramic substrate, the encapsulation material may be formed between the LED sub-assemblies. The encapsulation material may be the same material as the encapsulation material 40, the encapsulation material 40′, and/or the encapsulation material 606.

In some embodiments of the stage 750, forming the encapsulation material may include dispensing the encapsulation material on the lead frame or the ceramic substrate around the LED sub-assembly and/or between the LED sub-assemblies. The encapsulation material may be dispensed in an uncured, liquid state. The encapsulation material may be dispensed utilizing one or more inkjet-like dispensers, where the droplets of the encapsulation material are dispensed around the LED sub-assembly and/or between the LED sub-assemblies via the inkjet-like dispensers. The encapsulation material may be cured to complete stage 750.

In other embodiments of the stage 750, forming the encapsulation material may include using a molding process to produce the encapsulation material on the lead frame or the ceramic substrate. The molding process may comprise a compression molding process or an injection molding process. The encapsulation material may fill the space around the LED sub-assembly and may cover the LED sub-assembly. A removal process (such as grinding or sandblasting) may be applied to remove a portion of the encapsulation material to expose a top surface (such as the second surface 34b and/or the second surface 620b) of the wavelength conversion layer. In other embodiments, the top surface of the wavelength conversion layer may be left exposed by the molding process and the removal process may be omitted.

FIG. 11 illustrates a product that may be produced by performing stage 750. In particular, one or more LED sub-assemblies 130 may be attached to the lead frame 120 or the ceramic substrate with encapsulation material 140 formed between the LED sub-assemblies 130. In the illustrated embodiment, three LED sub-assemblies 130 are shown attached to the lead frame 120 or the ceramic substrate, although it should be understood that more or less LED sub-assemblies 130 may be attached to the lead frame 120 or the ceramic substrate in other embodiments. Each of the LED sub-assemblies 130 attached to the lead frame 120 or the ceramic substrate with the encapsulation material 140 on the sides of the LED sub-assemblies 130 may comprise an LED device.

In stage 760, LED devices may be separated. For example, the LED devices formed by stage 750 may be diced into individual LED devices or a certain number of LED devices may be separated from the other LED devices. The dicing the LED devices may be performed by cutting the encapsulation material and the lead frame or the ceramic substrate between the LED sub-assemblies to separate the LED devices. In some embodiments, stage 760 may be omitted where a single LED device is formed on the lead frame or ceramic substrate, or a desired end product may have multiple LED devices connected together.

FIG. 1J illustrates a product that may be produced by performing stage 760. In particular, a single LED device 110 is illustrated. The LED device 110 may include a sub-assembly 130 coupled to the lead frame 120 or ceramic substrate with the sidewall 136 surrounding the sub-assembly 130.

FIG. 1L is a flow diagram of a method 800 according to one embodiment. The method 800 may include providing a lead frame and a high power LED sub-assembly in stage 810. The method 800 may further include attaching the high power LED sub-assembly to a lead frame in stage 820. The method 800 may further include dispensing an encapsulation material in a space surrounding the high power LED sub-assembly 830. As mentioned generally above, the steps illustrated in this flow diagram can include more steps not explicitly shown in this figure.

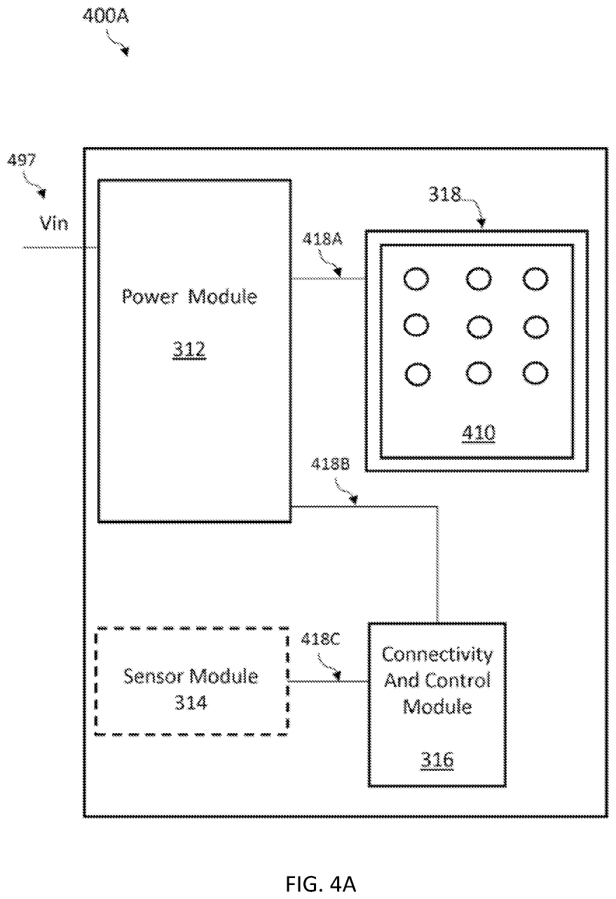

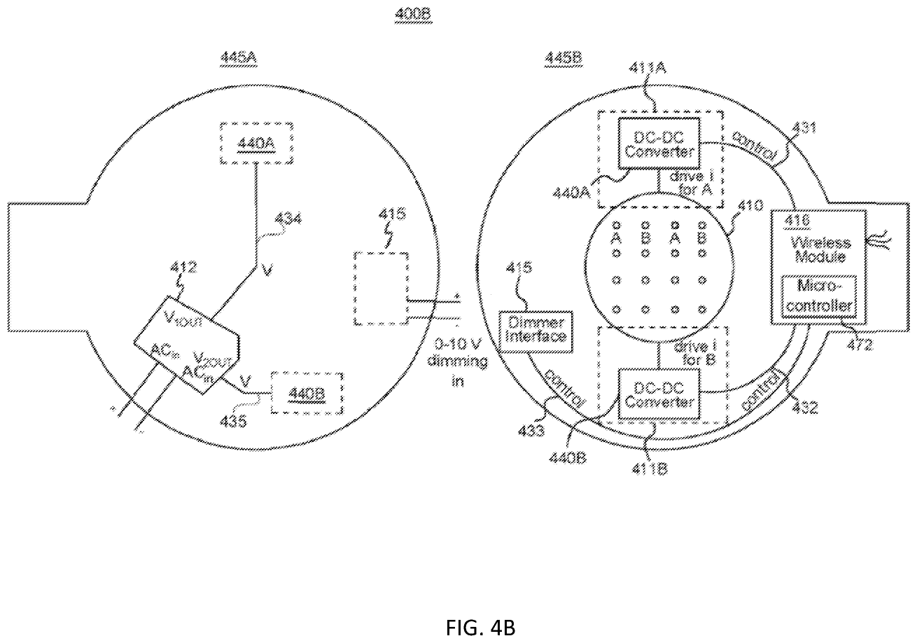

A method of operating a high power LED device, such as 10 or 10′ illustrated in FIGS. 1A and 1B may include supplying electrical current from the lead frame 20 to the LED die 32 via the metallic contact 22 such that the LED die 32 emits light. The emitted light (indicated by the arrows in FIG. 1A extending from the LED die 32) may be directed to the wavelength conversion layer 34, and through the sidewall 36 to be reflected by the encapsulation material 40 back into the LED die and/or the wavelength conversion layer 34 for eventual down conversion by the wavelength conversion layer 34. Electrical current can be provided from an external power source and provide to the LED device via a DC/DC converter on the same or different electronics board on which the LED device is mounted. Example systems including a DC/DC converter, and possible arrangements of the DC/DC converter in relation to an LED array that may include a plurality of the LED devices described herein as pixels, on one or more electronics boards are shown in FIGS. 3, 4A, 4B, 4C, 4D and 4E and described in more detail below.

FIG. 1M is a flow diagram of an example method 900 of producing an LED device according to some embodiments. For example, the method 900 may be utilized for producing the LED device 10 of FIG. 1A, the LED device 10′ of FIG. 1B, and/or the LED device 600 of FIG. 1C.

In stage 910, an LED die (such as the LED die 32, and/or the LED die 614) may be attached to a lead frame (such as the lead frame 20 and/or the lead frame 20′) or a ceramic substrate (such as the ceramic substrate 602). Attaching the LED die to the lead frame or the ceramic substrate may include positioning the LED die on the lead frame or the ceramic substrate. Positioning the LED die on lead frame or the ceramic substrate may include aligning metallic contacts (such as the metallic contacts 22 and/or the metallic contacts 616) and interconnects (such as the interconnects 25 and/or the interconnects 618) with the LED die and the lead frame or the ceramic substrate. In some embodiments, the metallic contacts and the interconnects may be connected to the LED die, and the metallic contacts and the interconnects may be utilized for soldering the LED die to the lead frame or the ceramic substrate to attach the LED die to the lead frame or the ceramic substrate. Soldering the LED die to the lead frame or the ceramic substrate may further electrically couple the die to the lead frame or the ceramic substrate.

In stage 920, LED dies are separated. In particular, the lead frame or ceramic substrate may be diced to separate LED dies from each other. The lead frame or ceramic substrate may be cut between adjacent LED dies to dice the separate LED dies. The dicing may result in each of the LED dies being divided into separate LED dies coupled to pieces of the lead frame or ceramic substrate. In some embodiments, stage 920 may be omitted, such as where a single LED die is attached to a lead frame or ceramic substrate.

In stage 930, the LED die may be attached to a wavelength conversion layer (such as the wavelength conversion layer 34, and/or the wavelength conversion layer 620). In stage 940, sidewalls (such as sidewall 36, and/or sidewall 622 may be formed. Depending on the embodiment of the method 900, the stage 930 and the stage 940 can be performed together or performed separately.

In some embodiments of the method 900 where stage 930 and stage 940 are performed together, silicone may be applied to a surface of either or both of the LED die and the wavelength conversion layer. The silicone may be applied to a center of the surface or surfaces. A certain amount of silicone (such as between 1 milligram and 999 milligrams) may be applied to the surface or surfaces. The silicone may be applied to a surface of either or both of the LED die and the wavelength conversion layer that is to be attached against the other component. The silicone may be the same material as the material of the sidewall 36 and/or the sidewall 622 and the silicone may be applied in an uncured state. The LED die and the wavelength conversion layer may be positioned against each other with the surface or surfaces of the LED die and/or the wavelength conversion layer abutting the other component. As the LED die and the wavelength conversion layer are positioned against each other, a portion of the silicon may be forced outside the area between the LED die and the wavelength conversion layer, and may extend around the sides of the LED die. Due to capillary forces, the portion of the silicon forced outside of the area between the LED and the wavelength conversion layer may form the shape of the sidewall 36 and/or the sidewall 622. For example, the portion of the silicone may form the angled or curved profile shown by the sidewall 36 and/or the sidewall 622. The angle or curvature of the profile formed by the silicone may depend on the amount of silicone applied to the surface or surfaces. With the LED die and the wavelength conversion layer positioned against each other, the silicone may be cured, thereby attaching the LED die to the wavelength conversion layer and forming the sidewall.

In some other embodiments of the method 900 where stage 930 and stage 940 are performed separately, the wavelength conversion layer may be partially cured and the LED die may be positioned against the wavelength conversion layer while partially cured in stage 930. The material of the partially cured wavelength conversion layer may form a bond with the LED die when the LED die is positioned against the wavelength conversion layer. The wavelength conversion layer may then be fully cured and the LED die may be attached with the wavelength conversion layer to complete stage 930. In stage 940, silicone may be applied to the sides of the LED die after the LED die has been attached with the wavelength conversion layer. The silicone may be applied in an uncured state. Due to capillary forces, the silicone may form the shape of the sidewall 36 and/or the sidewall 622. For example, the silicone may form the angled or curved profile shown by the sidewall 36 and/or the sidewall 622. The angle or curvature of the profile formed by the silicone may depend on the amount of silicone applied to the sides of the LED die. The silicone may be cured, thereby forming the sidewall. The LED die attached to the wavelength conversion layer with the sidewall may be referred to as an LED sub-assembly.

In stage 950, an encapsulation material may be formed. The encapsulation material may be formed on the wavelength conversion layer, and around an LED sub-assembly on the wavelength conversion layer. In embodiments where there are multiple LED sub-assemblies attached to the wavelength conversion layer, the encapsulation material may be formed between the LED sub-assemblies. The encapsulation material may be the same material as the encapsulation material 40, the encapsulation material 40′, and/or the encapsulation material 606.

In some embodiments of the stage 950, forming the encapsulation material may include dispensing the encapsulation material on the wavelength conversion layer around the LED sub-assembly and/or between the LED sub-assemblies. The encapsulation material may be dispensed in an uncured, liquid state. The encapsulation material may be dispensed utilizing one or more inkjet-like dispensers, where the droplets of the encapsulation material are dispensed around the LED sub-assembly and/or between the LED sub-assemblies via the inkjet-like dispensers. The encapsulation material may be cured to complete stage 950.

In other embodiments of the stage 950, forming the encapsulation material may include using a molding process to produce the encapsulation material on the wavelength conversion material. The molding process may comprise a compression molding process or an injection molding process. The encapsulation material may fill the space around the LED sub-assembly. The top surface (such as the second surface 34b and/or the second surface 620b) of the wavelength conversion layer may be left exposed by the molding process.

In other embodiments of the method 900, stage 960 may be performed prior to stage 950. In particular, LED sub-assemblies may be separated into individual LED sub-assemblies prior to the formation of the encapsulation material. The LED sub-assemblies may be separated by dicing (i.e., cutting) the wavelength conversion layer to separate the individual LED sub-assemblies. Stage 950 may then be performed to produce the encapsulation material. In these embodiments, the encapsulation material may be formed on the lead frame or the ceramic layer and may extend along at least a portion of the sides of the wavelength conversion material. In embodiments where the molding process is utilized to form the encapsulation material, the molding process may result in the LED sub-assembly being covered by the encapsulation material. In these embodiments, stage 950 may further a removal process (such as grinding or sandblasting) may be applied to remove a portion of the encapsulation material to expose a top surface of the wavelength conversion layer.

In stage 960, LED devices may be separated. For example, the LED devices formed by stage 950 may be diced into individual LED devices or a certain number of LED devices may be separated from the other LED devices. The dicing the LED devices may be performed by cutting the encapsulation material and the wavelength conversion layer between the LED sub-assemblies to separate the LED devices. In some embodiments, stage 960 may be omitted where a single LED device is formed on the wavelength conversion layer, or a desired end product may have multiple LED devices connected together.

FIG. 2A is a diagram of an LED device 200 in an example embodiment. The LED device 200 may include a substrate 202, an active layer 204, a wavelength conversion layer 206, and primary optic 208. In other embodiments, an LED device may not include a wavelength converter layer and/or primary optics. The substrate 202 and active layer 204 correspond to the die 32 as shown in FIGS. 1A and 1B.

As shown in FIG. 2A, the active layer 204 may be adjacent to the substrate 202 and emits light when excited. Suitable materials used to form the substrate 202 and the active layer 204 include sapphire, SiC, GaN, Silicone and may more specifically be formed from a III-V semiconductors including, but not limited to, AlN, AlP, AlAs, AlSb, GaN, GaP, GaAs, GaSb, InN, InP, InAs, InSb, II-VI semiconductors including, but not limited to, ZnS, ZnSe, CdSe, CdTe, group IV semiconductors including, but not limited to Ge, Si, SiC, and mixtures or alloys thereof.

The wavelength conversion layer 206 may be remote from, proximal to, or directly above active layer 204. The active layer 204 emits light into the wavelength conversion layer 206. The wavelength conversion layer 206 acts to further modify wavelength of the emitted light by the active layer 204. LED devices that include a wavelength conversion layer are often referred to as phosphor converted LEDs (“POLED”). The wavelength conversion layer 206 may include any luminescent material, such as, for example, phosphor particles in a transparent or translucent binder or matrix, or a ceramic phosphor element, which absorbs light of one wavelength and emits light of a different wavelength. The wavelength conversion layer may be the same as or similar to wavelength conversion layer 34 of FIGS. 1A and 1B.

The primary optic 208 may be on or over one or more layers of the LED device 200 and allow light to pass from the active layer 204 and/or the wavelength conversion layer 206 through the primary optic 208. The primary optic 208 may be a lens or encapsulate configured to protect the one or more layers and to, at least in part, shape the output of the LED device 200. Primary optic 208 may include transparent and/or semi-transparent material. In example embodiments, light via the primary optic may be emitted based on a Lambertian distribution pattern. It will be understood that one or more properties of the primary optic 208 may be modified to produce a light distribution pattern that is different than the Lambertian distribution pattern.

FIG. 2B shows a cross-sectional view of a lighting system 221 including an LED array 210 with pixels 201A, 201B, and 2010, as well as secondary optics 212 in an example embodiment. The LED array 210 includes pixels 201A, 201B, and 2010 each including a respective wavelength conversion layer 206B active layer 204B and a substrate 202B. The LED array 210 may be a monolithic LED array manufactured using wafer level processing techniques, a micro LED with sub-500 micron dimensions, or the like. Pixels 201A, 201B, and 2010, in the LED array 210 may be formed using array segmentation, or alternatively using pick and place techniques. Pixels 201A, 201B, and 201C may be similar to the pixels shown in FIG. 11.

The spaces 203 shown between one or more pixels 201A, 201B, and 2010 of the LED devices 200B may include an air gap or may be filled by a material such as a metal material which may be a contact (e.g., n-contact).

The secondary optics 212 may include one or both of the lens 209 and a reflector or waveguide 207. It will be understood that although secondary optics are discussed in accordance with the example shown, in example embodiments, the secondary optics 212 may be used to spread the incoming light (diverging optics), or to gather incoming light into a collimated beam (collimating optics). In example embodiments, the reflector or waveguide 207 may be a concentrator or a mixing device and may have any applicable shape to concentrate, diverge or direct light such as a parabolic shape, cone shape, beveled shape, or the like. The reflector or waveguide 207 may be coated with a dielectric material, a metallization layer, or the like used to reflect or redirect incident light. In alternative embodiments, a lighting system may not include one or more of the following: the wavelength conversion layer 206B, the primary optics 208B, the reflector or waveguide 207 and the lens 209.

Lens 209 may be formed form any applicable transparent material such as, but not limited to SiC, aluminum oxide, diamond, or the like or a combination thereof. Lens 209 may be used to modify the beam of light input into the lens 209 such that an output beam from the lens 209 will efficiently meet a desired photometric specification. Additionally, lens 209 may serve one or more aesthetic purpose, such as by determining a lit and/or unlit appearance of the p 201A, 201B and/or 2010 of the LED array 210.

FIG. 3 is a top view of an electronics board 310 for an integrated LED lighting system according to one embodiment. In alternative embodiments, two or more electronics boards may be used for the LED lighting system. For example, the LED array may be on a separate electronics board, or the sensor module may be on a separate electronics board. In the illustrated example, the electronics board 310 includes a power module 312, a sensor module 314, a connectivity and control module 316 and an LED attach region 318 reserved for attachment of an LED array to a substrate 320.

The substrate 320 may be any board capable of mechanically supporting, and providing electrical coupling to, electrical components, electronic components and/or electronic modules using conductive connecters, such as tracks, traces, pads, vias, and/or wires. The power module 312 may include electrical and/or electronic elements. In an example embodiment, the power module 312 includes an AC/DC conversion circuit, a DC/DC conversion circuit, a dimming circuit, and an LED driver circuit.

The sensor module 314 may include sensors needed for an application in which the LED array is to be implemented.

The connectivity and control module 316 may include the system microcontroller and any type of wired or wireless module configured to receive a control input from an external device.

The term module, as used herein, may refer to electrical and/or electronic components disposed on individual circuit boards that may be soldered to one or more electronics boards 310. The term module may, however, also refer to electrical and/or electronic components that provide similar functionality, but which may be individually soldered to one or more circuit boards in a same region or in different regions.

FIG. 4A is a top view of the electronics board 310 with an LED array 410 attached to the substrate 320 at the LED device attach region 318 in one embodiment. The electronics board 310 together with the LED array 410 represents an LED system 400A. Additionally, the power module 312 receives a voltage input at Vin 497 and control signals from the connectivity and control module 316 over traces 418B, and provides drive signals to the LED array 410 over traces 418A. The LED array 410 is turned on and off via the drive signals from the power module 312. In the embodiment shown in FIG. 4A, the connectivity and control module 316 receives sensor signals from the sensor module 314 over trace 4180.

FIG. 4B illustrates one embodiment of a two channel integrated LED lighting system with electronic components mounted on two surfaces of a circuit board 499. As shown in FIG. 4B, an LED lighting system 400B includes a first surface 445A having inputs to receive dimmer signals and AC power signals and an AC/DC converter circuit 412 mounted on it. The LED lighting system 400B includes a second surface 445B with the dimmer interface circuit 415, DC-DC converter circuit 440A and DC-DC converter circuit 440B, a connectivity and control module 416 (a wireless module in this example) having a microcontroller 472, and an LED array 410 mounted on it. The LED array 410 is driven by a first channel 411A and a second channel 411B, where the first channel 411A and the second channel 411B may be independent. In alternative embodiments, a single channel may be used to provide the drive signals to an LED array, or any number of multiple channels may be used to provide the drive signals to an LED array.

The LED array 410 may include two groups of LED devices. In an example embodiment, the LED devices of group A are electrically coupled to a first channel 411A and the LED devices of group B are electrically coupled to a second channel 411B. Each of the DC-DC converter circuit 440A and the DC-DC converter circuit 440B may provide a respective drive current via first channel 411A and second channel 411B, respectively, for driving a respective group of LEDs A and B in the LED array 410. The LEDs in one of the groups of LEDs may be configured to emit light having a different color point than the LEDs in the second group of LEDs. Control of the composite color point of light emitted by the LED array 410 may be tuned within a range by controlling the current and/or duty cycle applied by the DC-DC converter circuit 440A and the DC-DC converter circuit 440B via a first channel 411A and a second channel 411B, respectively. Although the embodiment shown in FIG. 4B does not include a sensor module (as described in FIG. 3 and FIG. 4A), an alternative embodiment may include a sensor module.

The illustrated LED lighting system 400B is an integrated system in which the LED array 410 and the circuitry for operating the LED array 410 are provided on a single electronics board. Connections between modules on the same surface of the circuit board 499 may be electrically coupled for exchanging, for example, voltages, currents, and control signals between modules, by surface or sub-surface interconnections, such as traces 431, 432, 433, 434 and 435 or metallizations (not shown). Connections between modules on opposite surfaces of the circuit board 499 may be electrically coupled by through board interconnections, such as vias and metallizations (not shown).

According to embodiments, LED systems may be provided where an LED array is on a separate electronics board from the driver and control circuitry. According to other embodiments, a LED system may have the LED array together with some of the electronics on an electronics board separate from the driver circuit. For example, an LED system may include a power conversion module and an LED module located on a separate electronics board than the LED arrays.

According to embodiments, an LED system may include a multi-channel LED driver circuit. For example, an LED module may include embedded LED calibration and setting data and, for example, three groups of LEDs. One of ordinary skill in the art will recognize that any number of groups of LEDs may be used consistent with one or more applications. Individual LEDs within each group may be arranged in series or in parallel and the light having different color points may be provided. For example, warm white light may be provided by a first group of LEDs, a cool white light may be provided by a second group of LEDs, and a neutral white light may be provided by a third group.

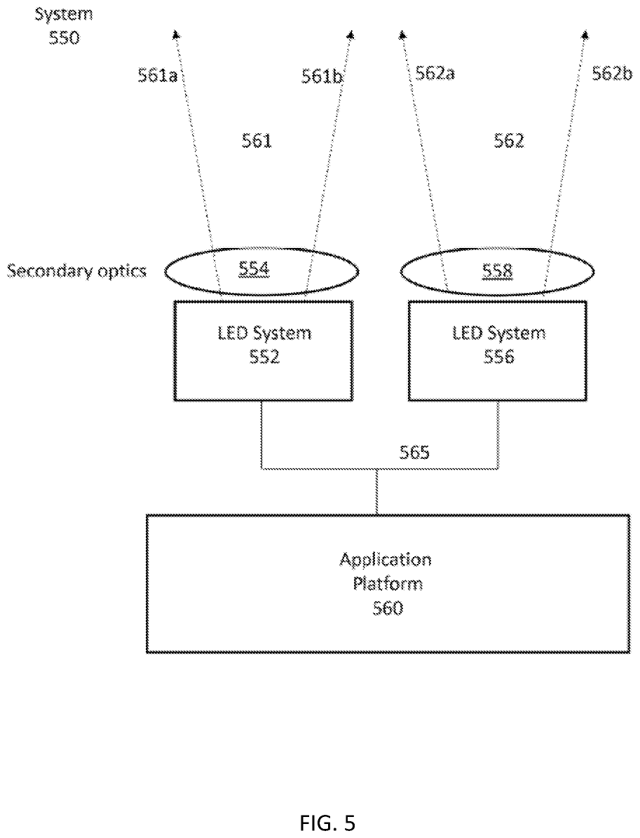

FIG. 5 shows an example system 550 which includes an application platform 560, LED system 552 and LED system 556, and secondary optics 554 and secondary optics 558. The LED system 552 and the LED system 556 may include LED sub-assembly 30 and lead frame 20, as shown in FIGS. 1A and 1B. The LED system 552 produces light beams 561 shown between arrows 561a and 561b. The LED system 556 may produce light beams 562 between arrows 562a and 562b. In the embodiment shown in FIG. 5, the light emitted from LED system 552 passes through secondary optics 554, and the light emitted from the LED system 556 passes through secondary optics 558. In alternative embodiments, the light beams 561 and 562 do not pass through any secondary optics. The secondary optics may be or may include one or more light guides. The one or more light guides may be edge lit or may have an interior opening that defines an interior edge of the light guide. LED system 552 and/or LED system 556 may be inserted in the interior openings of the one or more light guides such that they inject light into the interior edge (interior opening light guide) or exterior edge (edge lit light guide) of the one or more light guides. LEDs in LED system 552 and/or LED system 556 may be arranged around the circumference of a base that is part of the light guide. According to an implementation, the base may be thermally conductive. According to an implementation, the base may be coupled to a heat-dissipating element that is disposed over the light guide. The heat-dissipating element may be arranged to receive heat generated by the LEDs via the thermally conductive base and dissipate the received heat. The one or more light guides may allow light emitted by LED system 552 and LED system 556 to be shaped in a desired manner such as, for example, with a gradient, a chamfered distribution, a narrow distribution, a wide distribution, an angular distribution, or the like.

In example embodiments, the system 550 may be a mobile phone of a camera flash system, indoor residential or commercial lighting, outdoor light such as street lighting, an automobile, a medical device, AR/VR devices, and robotic devices. The integrated LED lighting system shown in FIG. 3, LED system 400A shown in FIG. 4A, illustrate LED system 552 and LED system 556 in example embodiments.

In example embodiments, the system 550 may be a mobile phone of a camera flash system, indoor residential or commercial lighting, outdoor light such as street lighting, an automobile, a medical device, AR/VR devices, and robotic devices. The LED system 400A shown in FIG. 4A and LED lighting system 400B shown in FIG. 4B illustrate LED system 552 and LED system 556 in example embodiments.

The application platform 560 may provide power to the LED system 552 and/or LED system 556 via a power bus via line 565 or other applicable input, as discussed herein. Further, application platform 560 may provide input signals via line 565 for the operation of the LED system 552 and LED system 556, which input may be based on a user input/preference, a sensed reading, a pre-programmed or autonomously determined output, or the like. One or more sensors may be internal or external to the housing of the application platform 560.

In various embodiments, application platform 560 sensors and/or LED system 552 and/or LED system 556 sensors may collect data such as visual data (e.g., LIDAR data, IR data, data collected via a camera, etc.), audio data, distance based data, movement data, environmental data, or the like or a combination thereof. The data may be related a physical item or entity such as an object, an individual, a vehicle, etc. For example, sensing equipment may collect object proximity data for an ADAS/AV based application, which may prioritize the detection and subsequent action based on the detection of a physical item or entity. The data may be collected based on emitting an optical signal by, for example, LED system 552 and/or LED system 556, such as an IR signal and collecting data based on the emitted optical signal. The data may be collected by a different component than the component that emits the optical signal for the data collection. Continuing the example, sensing equipment may be located on an automobile and may emit a beam using a vertical cavity surface-emitting laser (VCSEL). The one or more sensors may sense a response to the emitted beam or any other applicable input.

In example embodiment, application platform 560 may represent an automobile and LED system 552 and LED system 556 may represent automobile headlights. In various embodiments, the system 550 may represent an automobile with steerable light beams where LEDs may be selectively activated to provide steerable light. For example, an array of LEDs may be used to define or project a shape or pattern or illuminate only selected sections of a roadway. In an example embodiment, Infrared cameras or detector pixels within LED system 552 and/or LED system 556 may be sensors that identify portions of a scene (roadway, pedestrian crossing, etc.) that require illumination.

One of ordinary skill in the art would recognize from the present embodiments that the method and configuration described herein can be applied to any LED architecture.

The present embodiments can be implemented using standard manufacturing equipment according to known LED production assemblies and methods. The present embodiments can be incorporated into a modified flow of existing manufacturing process in LED die production.

The non-limiting methods and embodiments described herein for an LED assembly may be modified for a variety of applications and uses while remaining within the spirit and scope of the claims. The implementations and variations described herein, and/or shown in the drawings, are presented by way of example only and are not limiting as to the scope and spirit.

The descriptions herein may be applicable to all implementations of the method and system described herein although it may be described with respect to a particular implementation.

As described herein, the methods disclosed herein are not limited to any particular element(s) that perform(s) any particular function(s) and some steps of the methods presented need not necessarily occur in the order shown. For example, in some cases two or more method steps may occur in a different order or simultaneously.

In addition, some steps of the described methods may be optional (even if not explicitly stated to be optional) and, therefore, may be omitted. These and other variations of the methods disclosed herein will be readily apparent, especially in view of the description of the methods described herein, and are considered to be within the full scope of the embodiments.

Some features of implementations may be omitted or implemented with other implementations. The device or system elements and method elements described herein may be interchangeable and used in or omitted from any of the examples or implementations described herein.

Although features and elements are described above in particular combinations, each feature or element can be used alone without the other features and elements or in various combinations with or without other features and elements.

### EXAMPLES

Example 1 may include a light emitting diode (LED) comprising an LED die having a top, a bottom, and sidewalls, a first layer having a top and a bottom, with the first layer bottom being attached to the top of the LED die, the first layer being sized to be larger than the LED die, an at least partially transparent sidewall layer attached between the first layer and the sidewalls of the LED die, a reflective layer attached to the at least partially transparent sidewall layer, and a lead frame attached to the LED die.

Example 2 may include the LED of example 1, wherein the at least partially transparent sidewall layer defines a curved surface.

Example 3 may include the LED of example 1, wherein the at least partially transparent sidewall layer defines an angled surface.

Example 4 may include the LED of example 1, wherein the at least partially transparent sidewall layer is transparent to light of optical wavelengths of interest.

Example 5 may include the LED of example 1, wherein the reflective layer further comprises a polymeric material mixed with reflective particles.

Example 6 may include the LED of example 1, wherein the first layer is a wavelength conversion layer.

Example 7 may include the LED of example 1, wherein the first layer is a transparent layer.

Example 8 may include the LED of example 1, wherein the top of the first layer is flat.

Example 9 may include the LED of example 1, further comprising a base arranged to support the lead frame and define a cavity surrounding the LED die, first layer, and at least partially transparent sidewall layer, with a polymeric material mixed with reflective particles positioned between the base and the at least partially transparent sidewall layer.

Example 10 may include the LED of example 1, wherein the LED die, first layer, and at least partially transparent sidewall layer comprise a chip scale package.

Example 11 may include a method of forming a chip scale light emitting diode (LED) package, comprising the steps of attaching an LED die having a top, a bottom, and sidewalls to a first layer having a top and a bottom, with the first layer bottom being attached to the top of the LED die, the first layer being sized to be larger than the LED die, and attaching an at least partially transparent sidewall layer to extend between the first layer and the sidewalls of the LED die.

Example 12 may include the method of example 11, further comprising the step of attaching a lead frame to the LED die.

Example 13 may include the method of example 11, further comprising the step of attaching a combination of a base defining a cavity and lead frame to the LED die, with the LED die fitting within the base cavity.

Example 14 may include the method of example 11, further comprising the step of forming a reflective layer to contact the at least partially transparent sidewall layer.

Example 15 may include the method of example 11, further comprising the step of dispensing a polymeric material mixed with reflective particles to contact to the at least partially transparent sidewall layer and form a reflective layer.

Example 16 may include the method of example 11, further comprising the step attaching the at least partially transparent sidewall layer so as to define a curved surface.

Example 17 may include a method of forming a light emitting diode (LED) package, comprising the steps of providing a chip scale package comprising an LED die having a top, a bottom, and sidewalls, a first layer having a top and a bottom, with the first layer bottom being attached to the top of the LED die, the first layer being sized to be larger than the LED die, and an at least partially transparent sidewall layer that extends between the first layer and the sidewalls of the LED die, attaching the bottom of the LED die in the chip scale package to a lead frame, and forming a reflective layer attached to the at least partially transparent sidewall layer.

Example 18 may include the method of example 17, wherein the lead frame is attached to a base defining a cavity sized to fit the LED die within.

Example 19 may include the method of example 17, wherein the reflective layer comprises a polymeric material mixed with reflective particles to contact to the at least partially transparent sidewall layer.

Example 20 may include the method of example 17, wherein contacts in the lead frame are formed by at least one of etching and stamping.

Example 21 may include a light emitting diode (LED) device, comprising an LED die to emit light, a sidewall formed of a transparent material, the sidewall located at side walls of the LED die and surrounding the LED die, wherein the sidewall has an angled profile or a curved profile at an opposite of the sidewall from the LED die, and encapsulation material surrounding the sidewall, the encapsulation material comprising a reflective material, wherein the encapsulation material is to reflect a portion of the light emitted from the LED die toward a side of the LED device to which the light is to be emitted.

Example 22 may include the LED device of example 21, further comprising a lead frame attached to the LED die on a side of the LED die opposite from which the light is to be emitted from the LED device.

Example 23 may include the LED device of example 22, wherein a base of the lead frame comprises a polymer, wherein the lead frame includes metallic contacts, and wherein the lead frame is to provide current to the LED die for powering the LED die.

Example 24 may include the LED device of example 22, wherein the lead frame forms a pocket, wherein the LED die and the sidewall are located within the pocket, and wherein the encapsulation material fills at least a portion of the pocket surrounding the LED die and the sidewall.

Example 25 may include the LED device of example 22, wherein the side of the LED die is a first side of the LED die, wherein the LED device further comprises a wavelength conversion layer attached to the LED die on a second side of the LED die, the second side being opposite to the first side, wherein the side walls of the LED die extend between the first side of the LED die and the second side of the LED die.

Example 26 may include the LED device of example 21, further comprising a wavelength conversion layer attached to a side of the LED die, the side of the LED die being directed toward the side of the LED device to which the light is to be emitted.

Example 27 may include the LED device of example 26, wherein the wavelength conversion layer is wider than the LED die, and wherein the sidewall abuts a portion of the wavelength conversion layer that extends outside a footprint of the LED die.

Example 28 may include the LED device of example 21, wherein the reflective material comprises silicone mixed with titanium oxide particles.

Example 29 may include a method of producing a light emitting diode (LED) device, comprising depositing a sidewall on a wavelength conversion layer, the sidewall being deposited around an LED die on the wavelength conversion layer, the LED die on the wavelength conversion layer with the sidewall forming an LED sub-assembly, wherein the sidewall is formed of a transparent material, and depositing encapsulation material around the LED sub-assembly, wherein the encapsulation material is formed of a reflective material to reflect light from the LED die.

Example 30 may include the method of example 29, further comprising attaching a lead frame to the LED sub-assembly, wherein the lead frame is attached to an opposite side of the LED die from the wavelength conversion layer, and dicing the lead frame to produce the LED device.

Example 31 may include the method of example 30, wherein attaching the lead frame to the LED sub-assembly comprises soldering the lead frame to the LED sub-assembly.

Example 32 may include the method of example 29, further comprising attaching the LED die to the wavelength conversion layer.

Example 33 may include the method of example 32, wherein attaching the LED die to the wavelength conversion layer comprises applying silicone to a surface of the LED die, positioning the surface of the LED die against the wavelength conversion layer, wherein depositing the sidewall includes to allow a portion of the silicone to flow from between the LED die and the wavelength conversion layer, and wherein capillary forces cause the portion of the silicone to form an angled profile or curved profile, and curing the silicone to form the sidewall with the angled profile or the curved profile.

Example 34 may include the method of example 32, wherein attaching the LED die to the wavelength conversion layer comprises partially curing the wavelength conversion layer, positioning the LED die against the wavelength conversion layer while the wavelength conversion layer is partially cured, and fully curing the wavelength conversion layer with the LED die positioned against the wavelength conversion layer.

Example 35 may include the method of example 29, further comprising attaching a ceramic substrate to the LED sub-assembly, wherein the ceramic substrate is attached to an opposite side of the LED die from the wavelength conversion layer.

Example 36 may include the method of example 29, wherein depositing the encapsulation material around the LED sub-assembly comprises utilizing compression molding or injection molding to mold the encapsulation material around the LED sub-assembly, wherein the encapsulation material covers the LED sub-assembly, and removing a portion of the encapsulation material to expose a portion of the wavelength conversion layer.

Example 37 may include the method of example 29, wherein depositing the encapsulation material around the LED sub-assembly comprises utilizing one or more inkjet-like dispensers to dispense the encapsulation material around the LED sub-assembly, and allowing the encapsulation material to cure.

Example 38 may include a light emitting diode (LED) device, comprising an LED die to emit light, a ceramic substrate coupled to a first side of the LED die, a sidewall surrounding the LED die, the sidewall formed of a transparent material, wherein the sidewall abuts sides of the LED die, and wherein the sidewall has an angled profile or a curved profile at a side of the sidewall opposite to the LED die, and encapsulation material surrounding the sidewall, the encapsulation material comprising a reflective material, wherein the encapsulation material is to reflect a portion of the light.

Example 39 may include the LED device of example 38, further comprising a wavelength conversion layer coupled to a second side of the LED die, the second side of the LED die being opposite to the first side of the LED die, wherein the encapsulation material is to reflect the portion of the light toward the wavelength conversion layer.

Example 40 may include the LED device of example 38, wherein the ceramic substrate is coupled to the first side of the LED die via interconnects, wherein the ceramic substrate is to provide power to the LED die.

Having described the embodiments in detail, those skilled in the art will appreciate that, given the present description, modifications may be made to the embodiments described herein without departing from the spirit of the inventive concept. Therefore, it is not intended that the scope of the invention be limited to the specific embodiments illustrated and described.

What is claimed is:

1. A light emitting diode (LED) device, comprising:
an LED die to emit light;
a sidewall formed of a transparent material, the sidewall located at side walls of the LED die and surrounding the LED die, wherein the sidewall has an angled profile or a curved profile at an opposite of the sidewall from the LED die; and
encapsulation material surrounding the sidewall, the encapsulation material comprising a reflective material, wherein the encapsulation material is to reflect a portion of the light emitted from the LED die toward a side of the LED device to which the light is to be emitted.

2. The LED device of claim 1, further comprising:
a lead frame attached to the LED die on a side of the LED die opposite from which the light is to be emitted from the LED device.

3. The LED device of claim 2, wherein a base of the lead frame comprises a polymer, wherein the lead frame includes metallic contacts, and wherein the lead frame is to provide current to the LED die for powering the LED die.

4. The LED device of claim 2, wherein the lead frame forms a pocket, wherein the LED die and the sidewall are located within the pocket, and wherein the encapsulation material fills at least a portion of the pocket surrounding the LED die and the sidewall.

5. The LED device of claim 2, wherein the side of the LED die is a first side of the LED die, wherein the LED device further comprises:
a wavelength conversion layer attached to the LED die on a second side of the LED die, the second side being opposite to the first side, wherein the side walls of the LED die extend between the first side of the LED die and the second side of the LED die.

6. The LED device of claim 1, further comprising:
a wavelength conversion layer attached to a side of the LED die, the side of the LED die being directed toward the side of the LED device to which the light is to be emitted.

7. The LED device of claim 6, wherein the wavelength conversion layer is wider than the LED die, and wherein the sidewall abuts a portion of the wavelength conversion layer that extends outside a footprint of the LED die.

8. The LED device of claim 1, wherein the reflective material comprises silicone mixed with titanium oxide particles.

9. A method of producing a light emitting diode (LED) device, comprising:
depositing a sidewall on a wavelength conversion layer, the sidewall being deposited around an LED die on the wavelength conversion layer, the LED die on the wavelength conversion layer with the sidewall forming an LED sub-assembly, wherein the sidewall is formed of a transparent material; and
depositing encapsulation material around the LED sub-assembly, wherein the encapsulation material is formed of a reflective material to reflect light from the LED die.

10. The method of claim 9, further comprising:
attaching a lead frame to the LED sub-assembly, wherein the lead frame is attached to an opposite side of the LED die from the wavelength conversion layer; and
dicing the lead frame to produce the LED device.

11. The method of claim 10, wherein attaching the lead frame to the LED sub-assembly comprises soldering the lead frame to the LED sub-assembly.

12. The method of claim 9, further comprising:
attaching the LED die to the wavelength conversion layer.

13. The method of claim 12, wherein attaching the LED die to the wavelength conversion layer comprises:
applying silicone to a surface of the LED die;
positioning the surface of the LED die against the wavelength conversion layer, wherein depositing the sidewall includes to allow a portion of the silicone to flow from between the LED die and the wavelength conversion layer, and wherein capillary forces cause the portion of the silicone to form an angled profile or curved profile; and
curing the silicone to form the sidewall with the angled profile or the curved profile.

14. The method of claim 12, wherein attaching the LED die to the wavelength conversion layer comprises:
partially curing the wavelength conversion layer;
positioning the LED die against the wavelength conversion layer while the wavelength conversion layer is partially cured; and
fully curing the wavelength conversion layer with the LED die positioned against the wavelength conversion layer.

15. The method of claim 9, further comprising:
attaching a ceramic substrate to the LED sub-assembly, wherein the ceramic substrate is attached to an opposite side of the LED die from the wavelength conversion layer.

16. The method of claim 9, wherein depositing the encapsulation material around the LED sub-assembly comprises:
utilizing compression molding or injection molding to mold the encapsulation material around the LED sub-assembly, wherein the encapsulation material covers the LED sub-assembly; and
removing a portion of the encapsulation material to expose a portion of the wavelength conversion layer.

17. The method of claim 9, wherein depositing the encapsulation material around the LED sub-assembly comprises:
utilizing one or more inkjet-like dispensers to dispense the encapsulation material around the LED sub-assembly; and
allowing the encapsulation material to cure.

18. A light emitting diode (LED) device, comprising:
an LED die to emit light;
a ceramic substrate coupled to a first side of the LED die;
a sidewall surrounding the LED die, the sidewall formed of a transparent material, wherein the sidewall abuts sides of the LED die, and wherein the sidewall has an angled profile or a curved profile at a side of the sidewall opposite to the LED die; and
encapsulation material surrounding the sidewall, the encapsulation material comprising a reflective material, wherein the encapsulation material is to reflect a portion of the light.

19. The LED device of claim 18, further comprising:
a wavelength conversion layer coupled to a second side of the LED die, the second side of the LED die being opposite to the first side of the LED die, wherein the encapsulation material is to reflect the portion of the light toward the wavelength conversion layer.

20. The LED device of claim 18, wherein the ceramic substrate is coupled to the first side of the LED die via interconnects, wherein the ceramic substrate is to provide power to the LED die.
